(19) United States
(12) Patent Application Publication
(10) Pub. No.: US 2006/0057773 A1
(43) Pub. Date: Mar. 16, 2006

(54) Method for producing a stack of chips, a stack of chips and method for producing a chip for a multi-chip stack

(75) Inventor: Harald Gross, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 10/938,847

(22) Filed: Sep. 13, 2004

(51) Int. Cl. H01L 21/50

(52) U.S. Cl. 438/107; 438/109; 438/106

(57) ABSTRACT

A method for producing a stack of at least two chips that are electrically interconnected, a stack of chips and a method for producing a chip for a multi-chip stack. A capillary channel is routed in a provided chip from its lower to its upper side. The channel is sufficiently small to draw a liquid conductive material, e.g. heated solder from one to the other end of the channel by capillary forces. Several of these chips are assembled and bonded into a stack, whereby the channels of the chips are in line with each other to form a pipe. Then one end of the pipe is brought into contact with a liquid conducting material, filling the whole pipe by means of capillary forces. The chip comprises an electronic or an electric circuit that is connected by a conducting line with its filled channel. Therefore, several pipes constitute an electrical connecting network for the chips of the stack.

### TECHNICAL FIELD OF THE INVENTION

The present invention relates to a method for producing a stack of at least two chips that are electrically connected to each other, to a stack of chips that are arranged upon each other and electrically connected to each other, and to a method for producing a chip for a multi-chip stack.

### BACKGROUND OF THE INVENTION

Conventionally, various methods for producing a stack of chips are known. U.S. Pat. No. 5,656,553 describes a method for forming a monolithic electronic module by dicing wafer stacks. The fabrication method includes dicing a wafer of integrated circuit chips into a plurality of arrays of integrated circuit chips. The arrays of integrated circuit chips are then stacked to form an electronic module. A metallization pattern may be deposited in a substantially planar surface of the electronic module, and may be used to interconnect the various arrays of integrated circuit chips contained therein. In a further fabrication method, wafers comprising integrated circuit chips are stacked and aligned and mechanically fixed upon each other to form a stack by an adhesive. The wafer stack is then diced into rows and electrical interconnecting leads are formed at the side faces of the diced wafer rows. In this embodiment, the chips of the wafers comprise electrical contacting areas at a side face of the chip. This allows an electrical connection using interconnecting leads that are arranged at a side face of the stack. U.S. Pat. No. 6,072,234 describes a stack of equal layer neo-chips containing encapsulated IC chips of different sizes. Neo-chips suitable for stacking in 3D multi-layer electronic modules are formed by embedding IC chips into epoxy material that provides sufficient layer rigidity after curing. The encapsulated chips are formed by placing separate IC chips in a neo-wafer which is subjected to certain process steps and then diced to form neo-chips. The diced neo-chips are stacked to a multi-layer electronic module. Each neo-chip comprises an IC chip that is encapsulated in an insulating plate whereby wires are arranged in the plate that are filled with metal disposing an electrical contact for contacting pads of the IC chip.

### SUMMARY OF THE INVENTION

The present invention provides a method for producing a stack of chips that are electrically connected to each other with a better electrical connection between the chips. Additionally, the invention provides a stack comprising several chips that are electrically connected to each other with an improved electrical connection. Finally, the present invention provides a method for fabricating chips for a multi-chip stack that may be connected to each other more easily.

In one embodiment of the invention, there is a method for producing a stack of at least two chips that are electrically connected, including:

A capillary channel is integrated into each chip that is guided from an upper side to a lower side of each chip; the capillary channels are sufficiently small to draw conductive fluids from one end to the other end by capillary forces, as conductive fluid, for example a fluid solder is used. The chips are stacked on top of each other and aligned. Due to the alignment, the capillary channels form a pipe from the top to the bottom of the stack. One opening of the pipe is brought into contact with the conductive fluid. The fluid is drawn into the pipe by means of capillary forces.

This method has one advantage that the electrical conduits are easily fabricated by using capillary channels that make contact with the fluid solder. Because of the capillary force of the capillary channels, the whole channels are filled up with the fluid conductive materials, providing a network of conduits electrically connecting the chips of the stack. Furthermore, the described method has one advantage that the use of capillary channels requires less space. Therefore, the chips and the stack can be fabricated with a smaller size.

In another embodiment, the present invention is a stack of chips that are electrically interconnected. The electrical connections are constituted by a system of connected capillary channels that are arranged in the chips and filled up with electrically conductive material. At least one of the capillary channels is directed to a surface of the stack. The use of capillary channels for constituting conduits has the advantage that less space is required to provide the conduits and the filling up of the capillary channels is achieved by the capillary force of the capillary channels. Therefore, the system of the electrical interconnections between the chips of the stack are fabricated with high quality.

In still another embodiment, the present invention is a method for producing a chip for a multi-chip stack, whereby a circuit chip with an electrical circuit is provided, a rim portion is fixed at a rim of the circuit chip constituting one chip. A capillary channel is worked into the rim portion. A conduit is fabricated that is connected to the electrical circuit and guided to the capillary channel. This method has the advantage that the circuit chip can be fabricated independently from the rim portion and the material of the rim portion can differ from the material of the circuit chip. Therefore, a greater flexibility is given for producing the chip. The material for the rim portion can be specifically selected for an easy and precise method for fabricating a capillary channel in the rim portion.

In a preferred method, the stack is heated up to an elevated temperature before contacting the chips of the stack with liquid conductive material. This improves the filling-up of the capillary channels as the cooling down of the liquid material is attenuated.

In a further preferred embodiment of the method, the stack is arranged on an adhesive layer on a printed circuit board, the printed circuit board comprising solder areas beside the adhesive layer. The opening of the pipe is positioned on the solder area and the solder is heated up and drawn into the pipe.

In a further preferred embodiment of the method, the capillary channel is worked into the chip with the shape of a vertical tube with a wider opening face at the face of the chip. Furthermore, a capillary channel of an adjacent chip is arranged upon the wider opening face. This shape of the capillary channel has the advantage that the wider opening face is less susceptible to misalignment between the chips.

In a preferred embodiment of the stack, a recess is arranged at a face of a first chip, whereby the recess comprises a larger diameter in the plane of the face than a capillary channel. The recess is connected to the capillary channel of the first chip. The capillary channel of an adjacent second chip is guided to the recess of the first chip. The recess is covered by a face of the second chip. The recess has a shape that generates capillary forces in the fluid solder that is arranged in the capillary channel of the first and/or the second chip. The recess has the advantage that a fluid connection between the capillary channels of two adjacent chips can be achieved although the two chips are not exactly aligned. A slight deviation from an optimum position does not pose a problem due to the large face of the recess that allows a fluid connection between the capillary channels of two adjacent chips, although the capillary channels are not exactly in line.

In a preferred embodiment of the invention, the chip comprises a circuit chip with a rim portion made of a different material. The filled-up and electrically conductive capillary channel is embedded in the rim portion and connected with a conducting line of the circuit chip.

Preferably, a solder is used as a conducting material. Preferably, the circuit chip is a semiconductor element with an electronic circuit, for example a DRAM. In another embodiment, a conductive adhesive is used for filling up the pipe.

Preferably, the rim portion is made of a photo-sensitive epoxy material.

In a preferred embodiment of the method for producing a chip for a multi-chip stack, several circuit chips are arranged on a plate and the chips are embedded in an insulating material. For each circuit chip a capillary channel is integrated into the insulating material near the respective circuit chip. Subsequently, the conducting lines are produced between the circuit chip and the respective capillary channel. After this, single chips comprising the circuit chip and a rim portion are diced by introducing trenches into the insulating material.

Preferably, the capillary channel is integrated into the rim portion in a top face of the rim portion not guided through the whole thickness of the rim portion. Then the chip is thinned from the bottom face, until the capillary channel is opened on a bottom face of the rim portion.

Preferably, the rim portion is made of a material that can be structured by photolithographic processes. For structuring the rim portion and producing the capillary channel, photolithographic and etching processes with masking layers are used. Photolithographic and etching processes with masking layers are well-known and can be used for precise structuring the rim portion and fabricating the capillary channel.

### BRIEF DESCRIPTION OF THE DRAWINGS

These and other objects and features of the present invention will become clear from the following description taken in conjunction with the accompanying drawings in which:

FIGS. 1 to 8 illustrate various processing steps of producing a chip with a circuit chip and a rim portion with a capillary channel.

FIG. 9 illustrates a stack of aligned chips with a fixture arranged on a heating plate.

FIG. 10 illustrates a cross-sectional view of the stack of chips that is contacted with liquid solder.

FIG. 11 illustrates another embodiment of filling up the capillary channels of the stack of chips on a printed circuit board.

FIG. 12 illustrates a further embodiment of a stack of chips that are aligned with a clip and heated up for curing an adhesive that is arranged between the chips.

FIG. 13 illustrates the stack shown in FIG. 12 that is dipped with the capillary channels into liquid solder at an elevated temperature.

FIG. 14 illustrates the embodiment of FIG. 12 that is mounted on a printed circuit board.

### DETAILED DESCRIPTION OF THE INVENTION

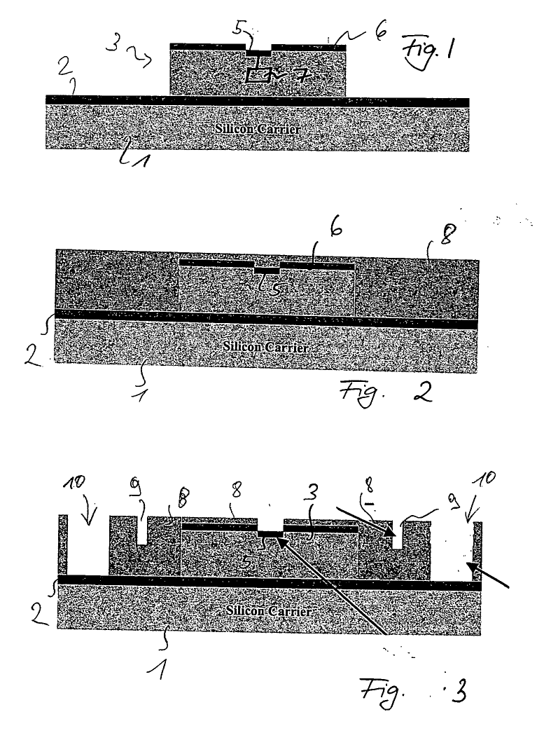

FIG. 1 shows a cross-sectional view of a plate 1 that is covered with an adhesive layer 2. On the adhesive layer 2, a circuit chip 3 with an electric or an electronic circuit 7 is arranged. The circuit 7 is electrically connected to a contacting pad 5 that is arranged on a top face of the circuit chip 3. Beside the contacting pad 5, the top surface of the circuit chip 3 is covered by a first layer 6. The first layer 6 e.g. consists of polyimide. The contacting pad 5 e.g. consists of aluminium or other metals. Depending on the embodiment, the plate 1 is e.g. constituted as a silicon wafer and the adhesive layer 2 is e.g. constituted as a thermal release tape.

If the plate 1 is constituted as a silicon wafer, FIG. 1 depicts only a part of the silicon wafer whereby a lot of circuit chips 3 with the same or other electric or electronic circuits 7 are arranged on the silicon wafer. The circuit chips 3 are fabricated with well-known semiconductor processes. The plate 1 is then covered with an insulating material 8, for example a photosensitive epoxy mate rial. Doing this, the circuit chip 3 is also covered with the insulating material.

FIG. 2 depicts a cross-sectional view of the circuit chip 3 that is covered with and embedded in the insulating material 8.

If there are several circuit chips 3 on the plate 1, all the circuit chips 3 are embedded in a layer of insulating material 8.

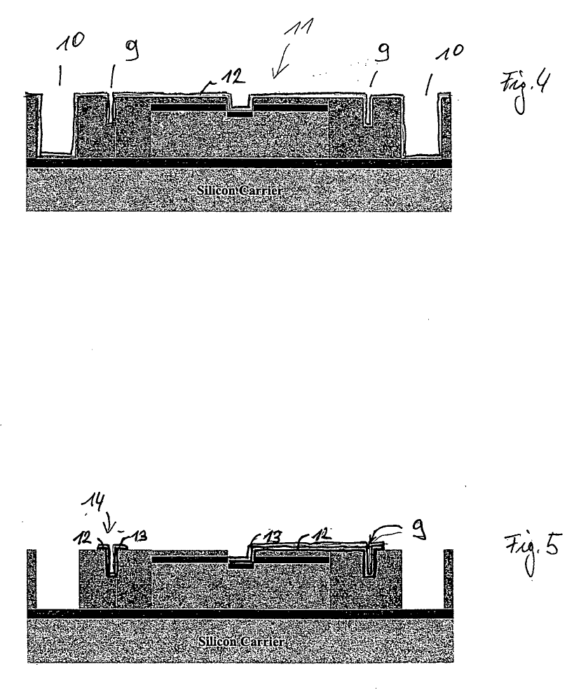

After this, a first lithographic process using masks and a developing process is used for introducing capillary channels 9 in the insulating material 8 beside the circuit chip 3. Depending on the embodiment, the capillary channel 9 is introduced from a top face of the insulating material 8 down to a given depth. The capillary channel 9 ends in the insulating material 8 and does not reach the adhesive layer 2. This embodiment is shown in FIG. 3. However, if it is of advantage, the capillary channels 9 might be introduced through the whole thickness of the insulating material 8 starting from a top face and ending at a bottom face that rests on a top face of the adhesive layer 2. The insulating material 8 is also removed from the contacting pad 5.

If there are several chips 11 on the plate 1, then the chips 11 are separated from each other by introducing a trench 10 into the insulating material 8, whereby a trench 10 surrounds the chip 11. The trench 10 is guided through the whole thickness of the insulating material 8. The trenches 10 separate the chips 11 that comprise a circuit chip 3 and a rim portion 12 with insulating material 8 and channels 9. Furthermore, the trenches 10 have the advantage that mechanical stress between the chips 11 is released.

After this step, a seed layer 12 is deposited on the structured surface of the wafer as shown in FIG. 4. The seed layer e.g. consists of titanium-copper. This process step is shown in FIG. 4.

Subsequently, a photo-resist layer is deposited on the seed layer 12. Then the photo-resist layer is structured by a lithographic processes and removed from a predetermined area of the seed layer 12 of a chip 11. A first predetermined area extends from the contacting pad 5 to the inner walls of a capillary channel 9. A second predetermined area is a circular area around a further capillary channel 9. As a photo-resist layer e.g. an electrophoretic resist is used. An electrically conductive material is then deposited on the free surfaces of the seed layer constituting a conducting line 13 and a further conducting area 14. The conducting line 13 connects the contacting pad 5 with the inner walls of the capillary channel 9. The metal is deposited e.g. by an electroplating process. In a following process the photo-resist layer and the areas of the seed layer 12 that are not covered with metal are removed. This process step is shown in FIG. 5.

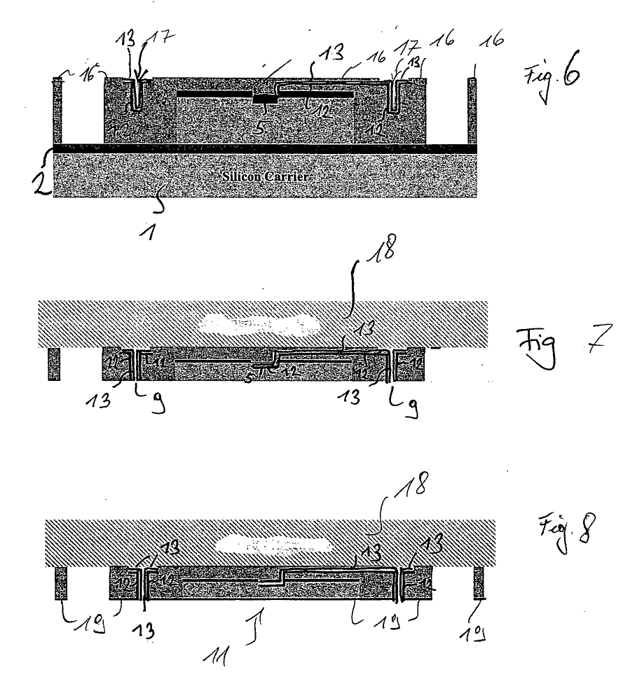

After this, a cover layer 16 is printed on the chip 11. The cover layer 16 comprises a recess 17 that is arranged around the opening of the capillary channels 9. Therefore the line area 13 and the further conducting area 14 are not covered by the cover layer 16 in a circular region around the respective capillary channel 9. The cover layer 16 is electrically insulating and for example made of the same material as the insulating material 8. Preferably, an epoxy is selected for the cover layer 16. This process step is shown in FIG. 6.

Thereafter, a handling plate 18 is mounted on the spacer layer 16, e.g. by gluing the handling plate 18 on the spacer layer 16. The plate 1 and the adhesive layer 2 are subsequently removed. In a following process, the chips 11 are ground from the bottom face to a smaller thickness. The chip 11 is at least thinned out to a thickness at which the channel 9 is opened from a bottom side of the chip 11. This process step is shown in FIG. 7.

In a further process step, a second adhesive layer 19 is printed on the bottom face of the chips 11. This process step is shown in FIG. 8. After this step, the handling plate is removed and several single chips 11 are obtained.

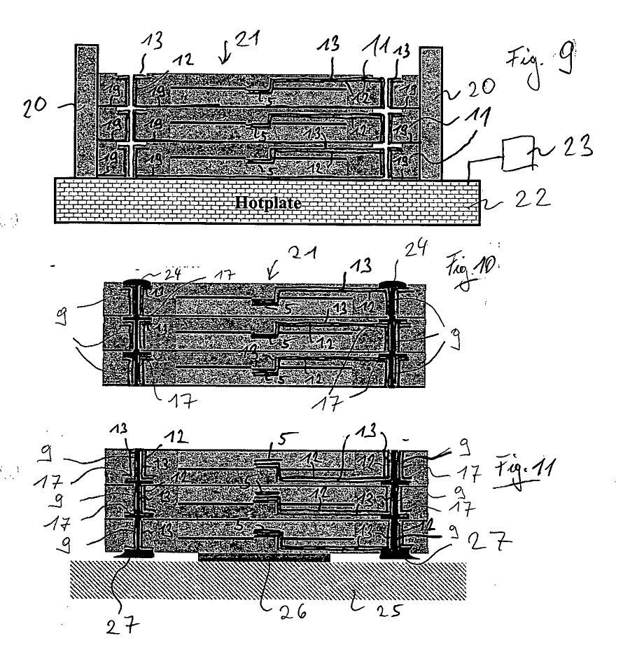

For producing a stack 21 of chips 11, the chips 11 are positioned in a fixture tool 20 that aligns several chips 11 as a stack. FIG. 9 shows the fixture tool 20 in which three chips 11 are aligned and piled up in a stack 21. The stack 21 is arranged on a heating plate 22. The heating plate 22 is controlled by a control unit 23 and heated up at a predetermined temperature. Between two chips 11, a second adhesive layer 19 is arranged that is heated up by the heating plate 22 and cured for fixing the three chips 11 to a stack 21.

The fixed stack 21 of chips 11 has an elevated temperature and the capillary channels 9 of at least one chip are is brought into contact with a liquid solder 24, as shown in FIG. 11.

The liquid solder 24 is in contact with openings of the capillary channels 9 and drawn by the capillary forces of the channels 9 into the channels 9. Also, the recesses 17 that are arranged between two chips 11 have such a shape as to provide a capillary force to the liquid solder 24. Therefore, the recesses 17 are filled up with the liquid solder, as well, and the liquid solder is guided from the capillary channel 9 of the chip 11 that is directly in contact with the liquid solder 24 to the capillary channels 9 of an adjacent chip 11 having an opening of the capillary channel directly adjacent to the recess 17. Due to the capillary force of the capillary channels 9, the whole system of capillary channels 9 that are connected to each other are filled up with the liquid solder. After cooling down the liquid solder 24, the capillary channels 9 are filled up with hard solder and therefore constitute conducting lines between the chips 11. In the shown embodiment, the channels 9 have the shape of cylindrical pipes that are arranged in one line. The filled-up channels 9 constitute conducting vias through the portion rims of the chips 11. The conducting lines 15 electrically connect the conducting pads 5 of the chip 11 to the conducting lines that are constituted by the system of filled-up channels 9. This process step is shown in FIG. 11.

A stack 21 may also be mounted on a printed circuit board 25. Preferably, the printed circuit board (PCB) 25 comprises an adhesive layer 26 upon which the stack 21 is positioned. Beside the adhesive layer 26, solder areas 27 are arranged on the PCB 25. The stack 21 is deposited on the adhesive layer 27, with openings of the channels 9 on the solder areas 27. Thereafter, the solder area 27 and preferably the stack 21 is heated to a temperature at which the solder of the solder area 27 becomes liquid. The liquid solder is drawn into the channels 9 by the capillary force of the capillary channels 9 that lie upon the solder area 27. The channels 9 of all the chips 11 of the stack 21 are filled up with solder, also filling up the recesses 17 that are arranged between capillary channels 9 of two adjacent chips 11. In a simple embodiment of the stack 21, the recesses 17 are not necessary. If the recesses 17 are missing, a high accuracy is necessary to bring the channels 9 of the different chips 11 into one line. If the channels 9 of adjacent chips 11 are not directly in one line, there might be a smaller opening between the two capillary channels 9 which is disadvantageous for the free flow of the fluid solder. FIG. 11 depicts a schematic sectional view of a printed circuit board 25 on which a stack 21 of chips 11 is arranged.

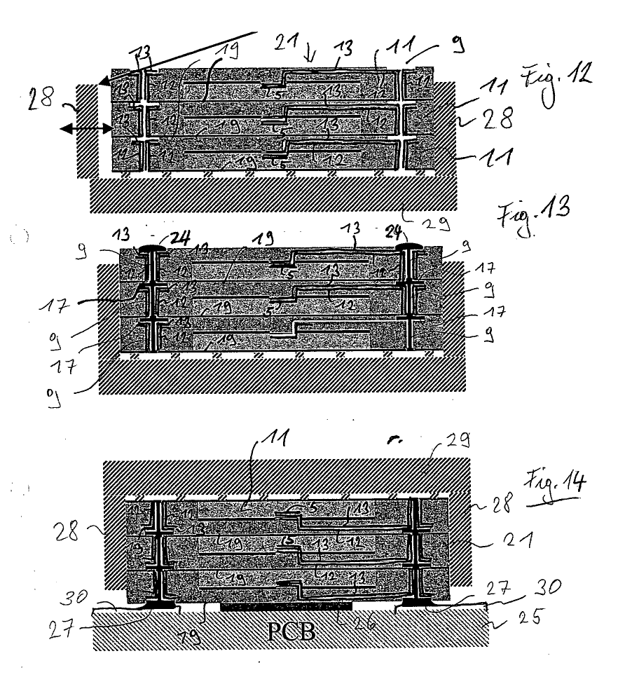

FIG. 12 depicts a further embodiment that uses a clip tool 28 with sidewalls for aligning the chips 11 in a stack 21. The stack 21 is positioned on an IC header 29. After aligning the chips 11, the second adhesive layers 19 that are arranged between two chips 11 are heated to cure. The stack 21 is subsequently dipped into liquid solder 24 by the openings of the channels 9. Preferably, the stack 21 has an elevated temperature that holds the liquid solder in the liquid phase. The liquid solder is drawn into the channels 9. The channels 9 and the recesses 17 are completely filled up with liquid solder 24.

Therefore, the pipes that are constituted by channels 9 are filled with the solder. There, the liquid solder is cooled down constituting electrical conduits within the capillary channels 9 that interconnect the chips 11.

FIG. 15 depicts a cross-sectional view of an IC header 29 in which a stack 21 is arranged and held by a clip tool 28. The stack 21 is positioned on an adhesive layer 26 of a printed circuit board 25. The opening of the channels 9 of the bottom phase of the stack 21 are positioned on liquid solder areas 27. The liquid solder areas 27 are positioned on circuit paths 30 of the printed circuit board 25. The liquid solder is drawn into the channels 9 by a capillary force so that the channels 9 and the recesses 17 that are interconnected are completely filled up with liquid solder. After cooling down the liquid solder in the channels 9 and the recesses 17, electrical conduits are constituted that electrically connect the chips 11 of the stack 21 and the electric and/or electronic circuits 7 of the chips 11.

The electric or electronic circuit 7 may be constituted as simple sensing electric circuits or as complex electronic circuits, e.g. DRAMs.

The conduits in the channels 9 constitute a system of electrical paths through the chips 11 and through the stack 21. The conduit system borders at openings on the bottom face and on the top face of the stack 21. The openings on the top face of the stack 21 assists the complete filling-up of the channel system since gas can be pushed out of the channels 9 by drawing in the liquid solder.

The discussed embodiments depict liquid solder as fluid conductive material. Depending on the embodiment, other fluid conductive materials can be used as well, e.g. a fluid uncured adhesion that is electrically conductive.

### REFERENCE LIST

1 plate
2 adhesive layer
3 circuit chip
4 silicon element
5 contacting pad
6 first layer
7 circuit
8 insulating material
9 channel
10 trench
11 chip
12 seed layer
13 conducting line
14 further conducting area
16 spacer layer
17 recess
18 handling plate
19 second adhesive layer
20 fixture tool
21 stack
22 heating plate
23 control unit
24 liquid solder
25 printed circuit board
26 adhesive layer
27 solder area
28 chip tool
29 IC header
30 circuit path

What is claimed is:

1. A method for producing a stack of at least two chips that are electrically connected, comprising:
fabricating a capillary channel in each chip from a top side to a bottom side of each chip;
stacking the chips on top of each other and aligning the chips, whereby alignment of the capillary channels of the chips form a pipe from top to bottom of the stack;
bringing one end of the pipe into contact with a liquid conductive material;
drawing the liquid conductive material into the pipe; and
altering a state of aggregation of the conductive material from liquid to solid to provide an electrical conduit that connects the chips of the stack.

2. The method according to claim 1, wherein the liquid conductive material is heated solder.

3. The method according to claim 1, wherein the liquid conductive material is an uncured conductive adhesive.

4. The method according to claim 1, wherein
the stack is attached to a printed circuit board with an adhesive, the printed circuit board comprising a solder area beside the adhesive, and
the capillary channels of the bottom chip are positioned on the solder area and the solder is heated up and drawn into the capillary channels from the bottom to the top chip.

5. The method according to claim 1, wherein
the capillary channels feature a vertical tube with a horizontal rectangular recess that is arranged between the two chips, and
the capillary channels of two chips are arranged in a vertical line.

6. A stack of chips electrically interconnected, comprising electrical conduits formed by capillary channels embedded in the chips and filled with electrically conductive material, wherein at least one capillary channel is routed to a surface of the stack.

7. The stack of chips according claim 6, further comprising:
at a face of a first chip, a recess integrated at an end of a capillary channel, the recess having a greater diameter in a plane of the face as the capillary channel of the first chip; and
an opening of a capillary channel of a second chip that is positioned above the recess, such that the recess provides a connection between capillary channels of two adjoining chips.

8. The stack of chips according to claim 6, wherein
each chip comprises an integrated circuit chip with a rim portion made of a different material,
the capillary channels are embedded in the rim portions,
conducting lines are provided between the integrated circuits of the chips and the conduits.

9. The stack of chips according to claim 6, wherein the electrically conductive material comprises solder.

10. The stack according to claim 6, wherein the circuit chip is a semiconductor element with integrated electronic circuits.

11. The stack according to claim 6, wherein the chip comprises a semiconductor element, the semiconductor element comprising a rim portion made of a different material, the electrical conduits being arranged in the rim portion, a conducting line is provided on the semiconductor chip and the rim portion electrically connecting the electrical circuit of the semiconductor chip with the electrical conduit.

12. Stack according to claim 6, wherein the rim portion is made of a photo-resist.

13. A method for producing a chip for a multi chip stack, comprising:
Providing an integrated circuit chip
Embedding the integrated circuit chip into a rim portion;
fabricating a capillary channel in the rim portion; and
producing a conducting line to interconnect the capillary channel and the integrated circuit chip.

14. The method according claim 13, wherein several circuit chips are arrayed on a plate, the chips are molded with an isolating material, a capillary channel is integrated in the isolating material, the conducting lines are batch fabricated for each circuit chip and the insulating material is trenched around each circuit chip providing single chips with a circuit chip and a rim portion with a capillary channel.

15. The method according to claim 14, wherein the capillary channel is fabricated into the rim portion from a top face as blind hole, and the chip with the rim portion is thinned from a bottom face until the capillary channel becomes a through hole.

16. The method according to claim 13, wherein the rim portion is made of a material configured to be structured by lithographic processes.

17. The method according to claim 16, wherein the material is a photo sensitive material and the process is photo lithography.
